(19) United States
(12) Patent Application Publication
(10) Pub. No.: US 2025/0343392 A1
(43) Pub. Date: Nov. 6, 2025

(54) SEMICONDUCTOR DEVICE

(71) Applicant: EPISTAR CORPORATION, Hsinchu (TW)

(72) Inventors: Chong-Ming HUANG, Hsinchu (TW); Yung-Hsiang LIN, Hsinchu (TW); Shiu-Han WU, Hsinchu (TW)

(21) Appl. No.: 18/655,996

(22) Filed: May 6, 2024

(51) Int. Cl. H01S 5/11; H01S 5/20; H01S 5/30; H01S 5/32; H01S 5/323

(52) U.S. Cl. CPC H01S 5/11; H01S 5/2031; H01S 5/3072; H01S 5/3211; H01S 5/32341

(57) ABSTRACT

A semiconductor device is provided. The semiconductor device includes a first semiconductor structure, a second semiconductor structure on the first semiconductor structure and an active structure between the first semiconductor structure and the second semiconductor structure. The first semiconductor structure includes a first waveguiding layer having a first band gap, and a first interlayer directly contacting the first waveguiding layer and having a first thickness and a second bandgap lager than the first band gap. The first thickness is 5 nm-35 nm.

### BACKGROUND

### Technical Field

The present disclosure relates to semiconductor device, and in particular to a laser semiconductor device.

### Description of the Related Art

Semiconductor elements are widely used, and the research and development of related materials are also continuously being carried out. For example, III-V semiconductor materials containing group III and group V elements may be applied to various optoelectronic semiconductor elements, such as light-emitting chips (light-emitting diodes or laser diodes), light-absorbing chips (photodetectors or solar cells) or non-luminous chips (power components of switches or rectifiers), which can be used in lighting, medical treatment, display, communication, sensing, power supply systems and other applications.

With the development of science and technology, there are still many technical research and development needs for semiconductor components. Although existing semiconductor devices have generally met various needs, they are not satisfactory in all aspects and further improvements are still needed.

### BRIEF SUMMARY

The present disclosure provides a semiconductor device. The semiconductor device includes a first semiconductor structure, a second semiconductor structure on the first semiconductor structure and an active structure between the first semiconductor structure and the second semiconductor structure. The first semiconductor structure includes a first waveguiding layer having a first band gap, and a first interlayer directly contacting the first waveguiding layer and having a first thickness and a second bandgap lager than the first band gap. The first thickness is 5 nm-35 nm.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion

FIG. 1 illustrates a cross-sectional view of a part of a semiconductor device in accordance with one embodiment of the present disclosure.

FIG. 2 illustrates a cross-sectional view of a part of a semiconductor device in accordance with one embodiment of the present disclosure.

FIG. 3 illustrates a cross-sectional view of a part of the semiconductor device in accordance with one embodiment of the present disclosure.

FIG. 4 illustrates a cross-sectional view of a semiconductor device in accordance with an embodiment of the present disclosure.

FIG. 5 illustrates a top-view of a semiconductor device in accordance with some embodiments of the present disclosure.

FIG. 6 illustrates a cross-sectional view of a semiconductor apparatus according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “below,” “lower,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

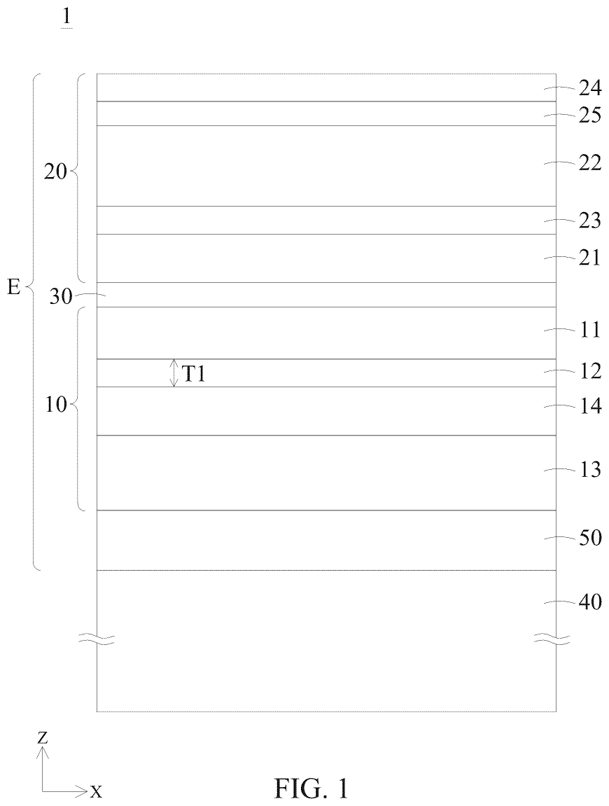

FIG. 1 shows a cross-sectional view of a part of a semiconductor device 1 in accordance with one embodiment of the present disclosure. The semiconductor device 1 includes an epitaxial stack E. The epitaxial stack E includes a first semiconductor structure 10, a second semiconductor structure 20 locates on the first semiconductor structure 10 and an active structure 30 between the first semiconductor structure 10 and the second semiconductor structure 20. The first semiconductor structure 10 includes a first waveguiding layer 11 and a first interlayer 12. The first waveguiding layer 11 locates between the active structure 30 and the first interlayer 12. The first interlayer 12 directly contacts the first waveguiding layer 11. The first waveguiding layer 11 has a first band gap, and the first interlayer 12 includes a second band gap larger than the first band gap. More specifically, in some embodiments, the material of the first waveguiding layer 11 is InₓGa₍₁₋ₓ₎N, wherein 0≤x≤0.1, and the first band gap is 3.2 eV˜3.4 eV. The material of the first interlayer 12 is Al_{y}Ga_{(1-y)}N, wherein 0.05<y<0.3, and the second band gap is 3.5 eV˜3.9 eV.

In the embodiment, the first semiconductor structure 10 further includes a first cladding layer 13, and the first interlayer 12 is between the first cladding layer 13 and the first waveguiding layer 11. Since the second band gap of the first interlayer 12 is larger than the first band gap of the first waveguiding layer 11, the current can laterally spread in the first interlayer 12, and therefore the heat generated from current crowding effect can be alleviated. In the embodiment, the first interlayer 12 includes a first thickness T1 along Z direction shown in FIG. 1, and the first thickness T1 is between 5 nm-35 nm. If the first thickness T1 is less than 5 nm, the current spreading effect will not be significant. If the first thickness T1 is more than 35 nm, the epitaxial quality will be deteriorated and the turn-on voltage of the semiconductor device 1 will rise. In other embodiments, the first thickness T1 is between 6 nm-20 nm. The first cladding layer 13 and the first interlayer 12 include same element compound, such as AlGaN or AlN. Compare with the semiconductor device without the first interlayer 12, the semiconductor device 1 in the embodiment has higher uniformity of optical property and electrical property (such as emitting power and the wall-plug-efficiency (WPE), and the semiconductor device 1 with the first interlayer 12 can even enhance the yield of producing high power (>4.5W) semiconductor device. In the embodiment, the first interlayer 12 is unintentionally or intentionally doped and includes a first dopant with a first doping concentration between 1×10¹⁶ atoms/cm³ and 1×10²⁰ atoms/cm³. The first dopant includes silicon (Si), carbon (C), germanium (Ge), tin (Sn), lead (Pb), or oxygen (O). In another embodiment, the first interlayer 12 is undoped.

In the embodiment, the first semiconductor structure 10 further optionally includes a first intermediate layer 14 between the first cladding layer 13 and the first interlayer 12. The first intermediate layer 14 has a refractive index lower than a refractive index of the first cladding layer 13, and therefore a light emitted from the active structure 30 can be confined due to the difference of the refractive indexes. In the embodiment, the first intermediate layer 14 has a band gap higher than the first band gap of the first waveguiding layer 11 and lower than the second band gap of the first interlayer 12. The first intermediate layer 14 includes GaN. The first intermediate layer 14 has a thickness larger than the first thickness T1 of the first interlayer 12. In the embodiment, a ratio of the first thickness T1 to the thickness of the first intermediate layer 14 is between 5 and 70. In the embodiment, the first intermediate layer 14 includes the first dopant with a doping concentration higher than the first doping concentration, for example, the doping concentration of the first intermediate layer 14 is between 1×10¹⁹ atoms/cm³ and 4×10¹⁹ atoms/cm³, and the first doping concentration of the first interlayer 12 is between 1×10¹⁸ atoms/cm³ and 5×10¹⁸ atoms/cm³.

The second semiconductor structure 20 includes a second waveguiding layer 21 and a second cladding layer 22, and the second waveguiding layer 21 is between the active structure 30 and the second cladding layer 22. According to some embodiments of the present disclosure, the active structure 30 is a light-emitting structure capable of radiating light out of the semiconductor device 1 along a Z-direction.

Each of the first cladding layer 13 and the second cladding layer 22 has a refractive index lower than a refractive index of the active structure 30. More specifically, the first cladding layer 13 has a first refractive index, the second cladding layer 22 comprises a second refractive index, and the active structure 30 has a third refractive index higher than the first refractive index and the second refractive index. Thus, the first cladding layers 13 and the second cladding layer 22 can confine the light generated from the active structure 30. In the embodiment, the first refractive index and/or the second refractive index are 2.2˜2.4, and the third refractive index is 2.4˜2.7.

The second semiconductor structure 20 can further optionally include a carrier blocking layer 23 between the second waveguiding layer 21 and the second cladding layer 22, a contact layer 24 on the second cladding layer 22, and a second intermediate layer 25 between the contact layer 24 and the second cladding layer 22. The carrier blocking layer 23 is able to block the carriers overflowing from the active structure 30. More specifically, the carrier blocking layer 23 includes a band gap higher than a band gap of the second waveguiding layer 21, so the carriers are hard to flow from the active structure 30 into the second cladding layer 22 for improving the combination rate of the electron and hole. In the embodiment, the carrier blocking layer 23 includes a fourth dopant with a fourth doping concentration and a fifth dopant with a fifth doping concentration. The fifth dopant is different from the fourth dopant, and the fourth doping concentration is much higher than the fifth doping concentration. For example, a ratio of the fourth doping concentration to the fifth doping concentration is 50˜250. The fourth dopant can be magnesium (Mg), lithium (Li), sodium (Na), potassium (K), beryllium (Be), zinc (Zn), or calcium (Ca), and the fourth dopant and the fifth dopant respectively belong to different groups in periodic table of elements. In the embodiment, the fourth dopant is magnesium (Mg) and the fifth dopant is carbon (C). Besides, the fifth doping concentration is lower than 5×10¹⁷ atoms/cm³. The contact layer 24 connects to an electrode (not shown) and includes a doping concentration higher than that of the second intermediate layer 25 and the second cladding layer 22. In the embodiment, the contact layer 24 includes a doping concentration higher than 1×10²⁰ atoms/cm³. The second intermediate layer 25 has a refractive index lower than a refractive index of the second cladding layer 22, and therefore a light emitted from the active structure 30 can be confined due to the difference of the refractive indexes.

The semiconductor device 1 can further optionally include a base 40, and the epitaxial stack E further includes optionally a buffer structure 50 between the base 40 and the first semiconductor structure 10. The first semiconductor structure 10, the second semiconductor structure 20 and the active structure 30 sequentially locate on the buffer structure 50. The buffer structure 50 can serve as a stress adjusting layer to reduce the crystal stress between the base 40 and the first semiconductor structure 10 and prevent surface irregularities, such as pits or other defects, from forming on a top surface of the first cladding layer 13. Therefore, less stress and strain are accumulated in the first cladding layer 13, which means fewer or no surface irregularity is observed on the top surface of the first cladding layer 13.

In some embodiments, the first cladding layer 13 and the second cladding layer 22 are doped and the doping of the first cladding layer 13 and the second cladding layer 22 may be conducted by in-situ doping during epitaxial growth and/or by implanting using dopants after epitaxial growth. The first cladding layer 13 may have a first conductive type, and the second cladding layer 22 may have a second conductive type. The first cladding layer 13 and the second cladding layer 22 may have different conductive types. For example, the first conductive type may be p-type to provide holes, and the second conductive type may be n-type to provide electrons, respectively. Alternatively, the first conductive type may be n-type to provide electrons, and the second conductive type may be p-type to provide holes, respectively. In the embodiment, the first semiconductor structure 10 may be the n-type semiconductor structure, such as a nitrogen-based semiconductor doped with the first dopant such as silicon (Si), carbon (C), germanium (Ge), tin (Sn), lead (Pb), or oxygen (O). The second semiconductor structure 20 may be the p-type semiconductor structure, such as a nitrogen-based semiconductor doped with the fourth dopant such as magnesium (Mg), lithium (Li), sodium (Na), potassium (K), beryllium (Be), zinc (Zn), or calcium (Ca). The nitrogen-based semiconductor may be represented by the general formula InₓAl_{y}Ga_{(1-x-y)}N (0≤x, 0≤y, x+y≤1).

In some embodiments, the active structure 30 may include a multi-quantum wells (MQWs) structure. The active structure 30 can emit light when operating the semiconductor device 1. The light emitted by the active structure 30 includes visible light or invisible light. The wavelength of the light emitted by the semiconductor device 1 depends on the composition of the material of the active structure 30. For example, when the material of the active structure 30 includes InGaN, the active structure 30 can emit blue light or deep blue light with a peak wavelength of 400 nm to 490 nm, the active structure 30 can emit green light with a peak wavelength of 490 nm to 550 nm, or the active structure 30 can emit red light with a peak wavelength of 560 nm to 650 nm When the material of the active structure 30 includes AlGaN or AlGaInN material, the active structure 30 can emit ultraviolet light with a peak wavelength of 250 nm to 400 nm. When the material of the active structure 30 includes InGaAs, InGaAsP, AlGaAs, or AlGalnAs material, the active structure 30 can emit infrared light with a peak wavelength of 700 nm to 1700 nm. When the material of the active structure 30 includes InGaP or AlGaInP material, the active structure 30 can emit red light with a peak wavelength of 610 nm to 700 nm, or the active structure 30 can emit yellow light with a peak wavelength of 530 nm to 600 nm.

In some embodiments, when forming the semiconductor device 1, the epitaxial stack E may be formed on another growth substrate (not shown) by an epitaxial growth process, such as metal-organic chemical vapor deposition (MOCVD), hydride vapor phase epitaxy (HVPE), molecular beam epitaxy (MBE), liquid phase epitaxy (LPE), vapor phase epitaxy (VPE), or other epitaxial growth processes. The epitaxial stack E is bonded to the base 40, and then the growth substrate is removed. A bonding layer (not shown) can be provided between the epitaxial structure E and the base 40 to enhance the bonding strength. The bonding layer can be light-transmitting materials, such as light-transmitting glue. The bonding layer includes silicon dioxide (SiO₂), aluminum oxide (Al₂O₃), silicon nitride (SiₓN_{y}), polyimide (PI), polybenzoxazole (PBO), epoxy resin (epoxy), benzocyclobutene (BCB), or a combination thereof. In other embodiments, the base 40 is a growth substrate, and the epitaxial stack E may be directly and epitaxially grown on the base 40. Therefore, in various embodiments of the present disclosure, the upper and lower positions of elements in various schematic diagrams are not intended to limit their forming sequence.

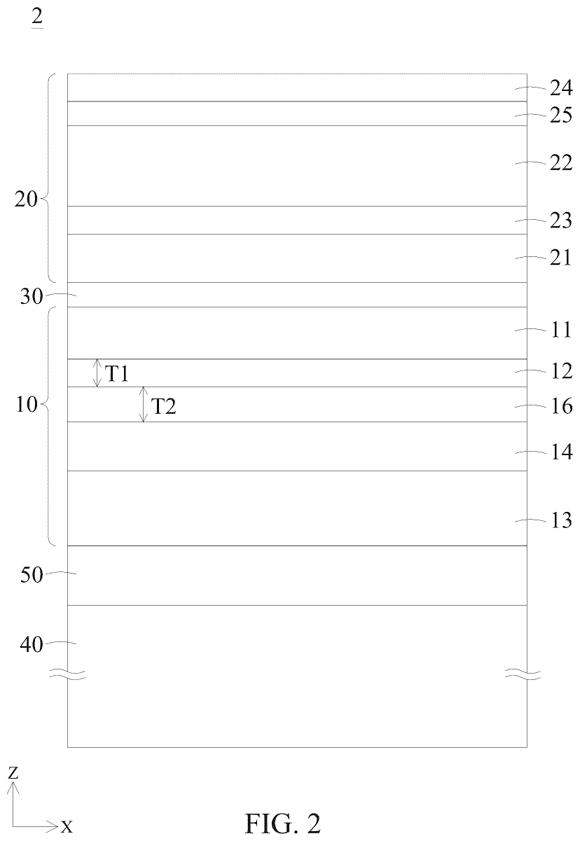

According to some embodiments of the present disclosure, FIG. 2 illustrates a cross-sectional view of a part of the semiconductor device 2. The structure shown in FIG. 2 is similar to the structure shown in FIG. 1, except that the first semiconductor structure 10 in the semiconductor device 2 further includes a second interlayer 16 between the first interlayer 12 and the first cladding layer 13. More specifically, in the embodiment, the second interlayer 16 directly connects to the first interlayer 12 and the first intermediate layer 14. The second interlayer 16 includes a third band gap higher than the first band gap of the first waveguiding layer 11 and lower than the second band gap of the first interlayer 12, and a second thickness T2 higher than the first thickness T1 of the first interlayer 12. The second thickness T2 is between 100 nm and 300 nm. In the embodiment, the second interlayer 16 includes GaN and the first interlayer 12 includes Alₓ₁Ga₍₁₋ₓ₁₎N (0.05≤ₓ₁≤0.45). In another embodiment, the second interlayer 16 includes Alₓ₂Ga₍₁₋ₓ₂₎N (0.01≤ₓ₂≤0.35) and the first interlayer 12 includes Alₓ₃In_{y}Ga_{(1-x3-y)}N (0.01≤ₓ₃≤0.5, 0.01≤y≤0.5). The second interlayer 16 includes a second dopant with a second doping concentration lower than the first doping concentration of the first interlayer 12. The second dopant includes silicon (Si) or carbon (C), and the second dopant and the first dopant include the same element. In the embodiment, the second interlayer 16 includes the second doping concentration less than 1×10¹⁷ atoms/cm³ and that is, the second interlayer 16 and the first interlayer 12 are undoped or unintentionally doped. In other embodiments, the second interlayer 16 is intentionally doped with the second dopant. Compare with the semiconductor device without the first interlayer 12 and the second interlayer 16, the semiconductor device 2 in the embodiment performs higher internal quantum efficiency (IQE) from a simulation result.

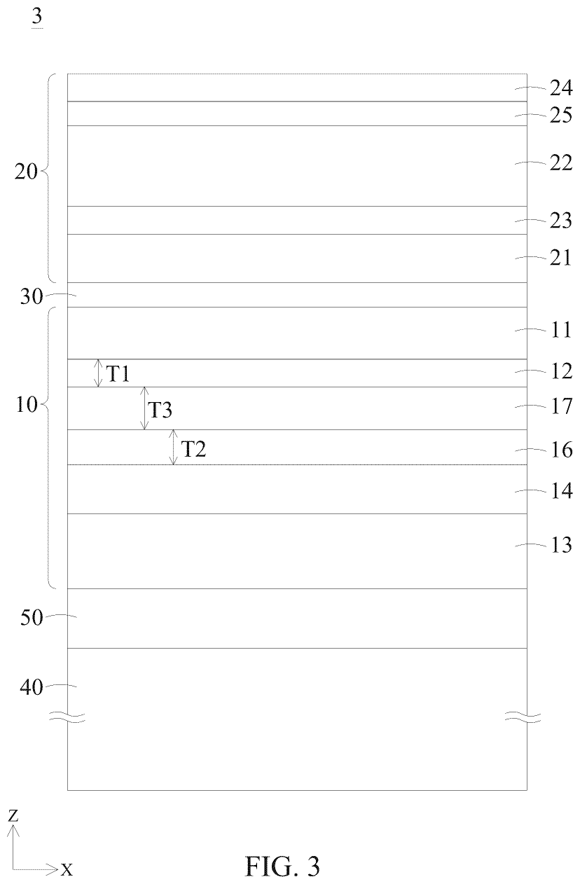

According to some embodiments of the present disclosure, FIG. 3 illustrates a cross-sectional view of a part of the semiconductor device 3. The structure shown in FIG. 3 is similar to the structure shown in FIG. 2, except that the first semiconductor structure 10 in the semiconductor device 3 further includes a third interlayer 17 between the first interlayer 12 and the second interlayer 16. The third interlayer 17 includes a fourth band gap higher than the second band gap of the first interlayer 12, and a third thickness T3 lower than the first thickness T1 of the first interlayer 12 and the second thickness T2 of the second interlayer 16. The third thickness T3 is between 0.1 nm and 2 nm. In the embodiment, the third interlayer 17 includes AlN, the second interlayer 16 includes GaN and the first interlayer 12 includes AlₓGa₍₁₋ₓ₎N (0.05≤x≤0.45). The third interlayer 17 includes a third dopant with a third doping concentration between 1×10¹⁶ atoms/cm³ and 1×10²¹ atoms/cm³. The third dopant includes silicon (Si) or carbon (C). In one embodiment, the third dopant, the second dopant and the first dopant include the same element. In the embodiments, the first doping concentration of the first interlayer 12, the second doping concentration of the second interlayer 16 and the third doping concentration of the third interlayer 17 are less than 1×10¹⁷ atoms/cm³ and that is, the first interlayer 12, the second interlayer 16 and the third interlayer 17 are undoped or unintentionally doped. In other embodiments, the third interlayer 17 is intentionally doped with the third dopant. Compare with the semiconductor device without the first interlayer 12, the second interlayer 16 and the third interlayer 17, the semiconductor device 3 in the embodiment has a higher power and a lower threshold current (Ith) from a simulation result.

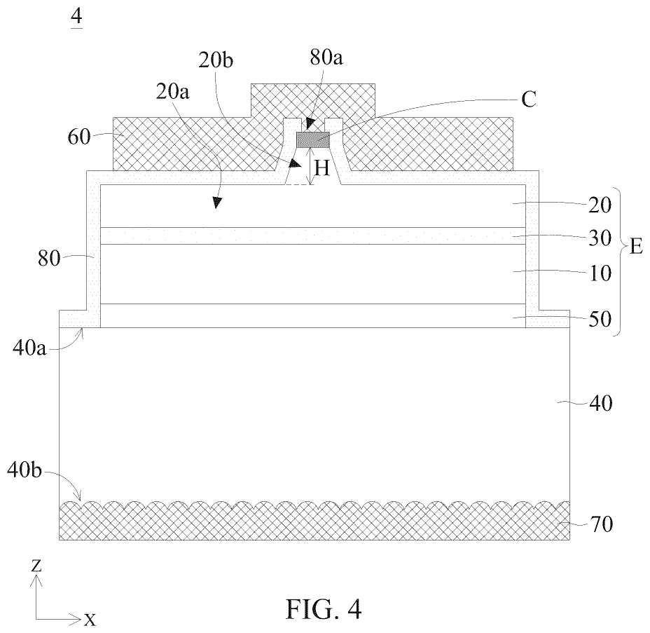

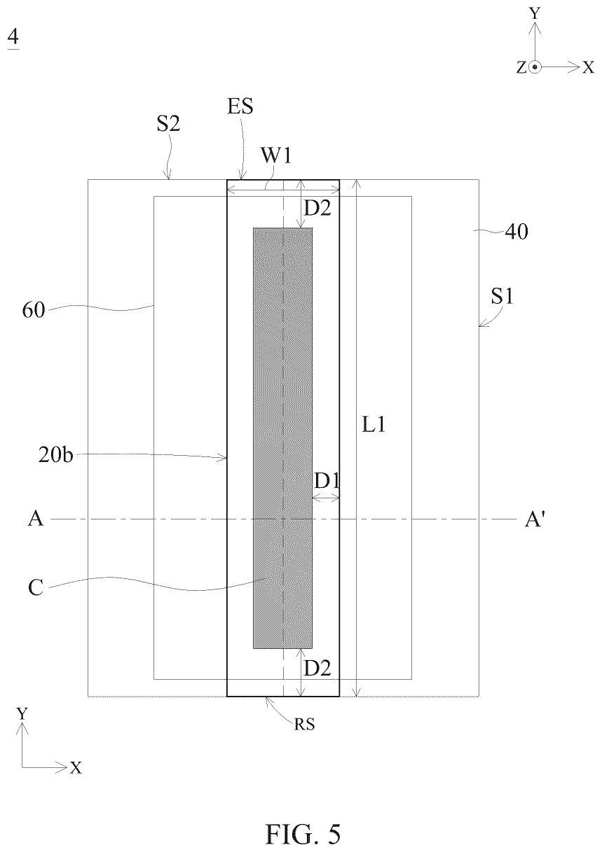

FIG. 4 is a schematic cross-sectional view of a semiconductor device 4 according to an embodiment corresponding to A-A′ line in FIG. 5 of the present disclosure. FIG. 5 illustrates a top-view of a semiconductor device in accordance with some embodiments of the present disclosure.

The semiconductor device 4 further includes an upper electrode 60 and a lower electrode 70 depositing on the opposite sides of the epitaxial stack E. More specifically, the upper electrode 60 locates on the epitaxial stack E and the lower electrode 70 locates below the base 40. In some embodiments, the material of the upper electrode 60 and the lower electrode 70 may include palladium (Pd), chromium (Cr), titanium (Ti), aluminum (Al), gold (Au), platinum (Pt), or alloy thereof.

The semiconductor device 4 may optionally include a protective structure 80. The protective structure 80 located under the upper electrode 60 and covering the first semiconductor structure 10, the active structure 30 and the second semiconductor structure 20. The protective structure 80 includes an oxide, nitride or oxynitride of silicon (Si), zirconium (Zr), aluminum (Al), or tantalum (Ta).

The second semiconductor structure 20 further includes a mesa 20a and a ridge 20b protruding from the mesa 20a. The semiconductor device 4 further includes a conductive layer C on the ridge 20b, and the conductive layer C electrically connects to the second semiconductor structure 20 and the upper electrode 60. The upper electrode 60 covers the ridge 20b and a part of the mesa 20a. The protective structure 80 covers the mesa 20a and includes an opening 80a exposing the conductive layer C, and the upper electrode 60 connects to the conductive layer C through the opening 80a.

The material of the conductive layer C can be transparent and includes a metal oxide or a metal. The metal oxide includes indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), zinc oxide (ZnO), indium cerium oxide (ICO), indium tungsten oxide (IWO), indium titanium oxide (ITiO), indium zinc oxide (IZO), indium gallium oxide (IGO)), gallium aluminum zinc oxide (GAZO) or a combination of the above materials. The metal includes aluminum, nickel, gold with a thickness less than 500 Angstroms.

In one embodiment, the base 40 can be further processed by patterning. For example, the base 40 can be patterned to form a rough surface, but it is not limited thereto. In detail, the base 40 has an upper surface 40a and a lower surface 40b opposite to the upper surface 40a. The upper surface 40a and the lower surface 40b of the base 40 in this embodiment have different roughnesses. The lower surface 40b has a roughened structure and has a rougher roughness than the upper surface 40a. The lower surface 40b connects to the lower electrode 70. The roughened structure of the lower surface 40b can increase the adhesion ability between the base 40 and the lower electrode 70.

As shown in FIG. 5, the upper surface 40a or the lower surface 40b of the base 40 has a first side S1 and a second side S2 connecting to the first side S1. The first side S1 may be parallel to the Y direction, and the second side S2 may be parallel to the X direction. In this embodiment, a shape of the base 40 is a rectangle. The first side S1 is longer than the second side S2. The ridge 20b includes a light emitting side ES and a reflecting side RS opposite to the light emitting side ES. The light emitting side ES and the reflecting side RS are perpendicular to the upper surface 40a or the lower surface 40b of the base 40. In the embodiment, the light emitting side ES and the reflecting side RS are substantially parallel to the second side S2. The light emitting side ES and the reflecting side RS of the semiconductor device 4 are substantially perpendicular to the first side S1 and form a resonant cavity. The light generated from the active structure 30 resonates back and forth between the light emitting side ES and the reflecting side RS so a coherent light is emitted and exits to the outside at the light emitting side ES.

In one embodiment of the present embodiment, a low-reflectivity structure (not shown) covers the light-emitting side ES of the ridge 20b, and a high-reflectivity structure (not shown) covers the reflective side RS of the ridge 20b. The low-reflectivity structure and the high-reflectivity structure include dielectric material. The low-reflectivity structure and the high reflectivity structure can be a single-layer film or a multi-layer film. The dielectric material includes oxide, nitride or nitrogen oxide, such as AlₓO_{y}(1<x, 1<y), SiOₓ(1<x), NbₓO_{y}(1<x, 1<y), TiOₓ(1<x), ZrOₓ(1<x). The reflectivity of the low-reflectivity structure is lower than that of the high-reflectivity structure. The low-reflectivity structure has a reflectivity of 85%˜95% and may contain metal oxides, such as Al₂O₃, or metal oxynitrides, such as AlNOₓ. The high reflectivity structure has a reflectivity of more than 90%, preferably more than 95%, and may include, for example, multiple pairs of SiO₂/Ta₂O₅ and include a layer of Al₂O₃ and a layer of SiO₂ respectively located on two opposite sides of the multiple pairs of SiO₂/Ta₂O₅.

The ridge 20b extends along a direction parallel to the first side S1 and has a rectangular shape. The ridge 20b has a length L1 is between 100 and 2000 μm, 400 and 1800 μm, 800 and 1600 μm, or between 1000 and 1500 μm. The ridge 20b has a width R1 is between 1 and 100 μm, 10 and 90 μm, 15 and 80 μm, or between 20 and 70 μm. The ridge 20b includes a height H as shown in FIG. 4, the height H is between 0.1 and 2 μm, 0.2 μm and 1 μm, or between 0.1 and 0.5 μm.

The conductive layer C can partially or completely cover the ridge 20b. In the embodiment shown in FIG. 5, the conductive layer C partially covers the ridge 20b and is spaced apart from the side of the ridge 20b parallel to the first side S1 in a first distance D1. For example, the first distance D1 is between 0.1 μm and 1.5 μm. In other embodiment, the conductive layer C completely covers the ridge 20b and even extends to cover the mesa 20a. In the embodiment, the conductive layer C is spaced apart from the light emitting side ES or the reflective side RS in a second distance D2. For example, the second distance D2 is greater than 5 μm but less than 25 μm. In other embodiment, the second distance is 0 μm, that is two edges of the conductive layer C are aligned with the light emitting side ES and the reflective side RS. respectively.

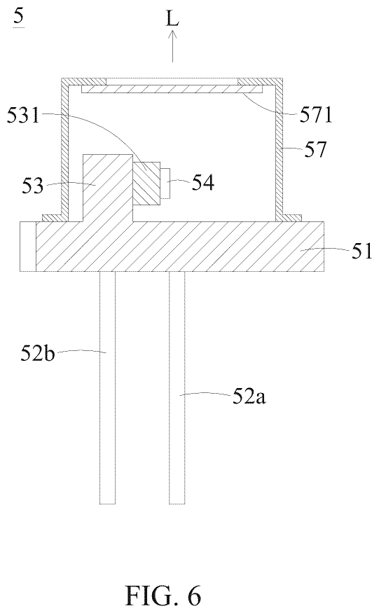

FIG. 6 illustrates a schematic cross-sectional view of a semiconductor apparatus 5 according to an embodiment of the present disclosure. The semiconductor apparatus 5 includes a heat sink 51, first pins 52a, second pins 52b, a fixed base 53, a secondary mounting base 531, a semiconductor device 54 and a metal cover 57. The first pin 52a and the second pin 52b are disposed on a bottom surface of the heat sink 51. The fixed base 53 is disposed on a top surface of the heat sink 51 and connected to the second pin 52b of the ground (GND). The secondary mounting base 531 is disposed on one side of the fixed base 53 and is connected with the semiconductor device 54. The metal cover 57 further includes a glass window 571 disposed on its top surface, and the metal cover 57 is joined to the heat sink 51. The semiconductor device 54 may be the semiconductor devices 1˜4 of the embodiment of the present disclosure. When the semiconductor apparatus 5 is connected to an external power source, the semiconductor device 54 can emit a laser light L toward the glass window 571 to leave the semiconductor apparatus 5.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a first semiconductor structure, comprising:
a first waveguiding layer comprising a first band gap; and
a first interlayer directly contacting the first waveguiding layer and comprising a first thickness and a second bandgap lager than the first band gap, and wherein the first thickness is 5 nm-35 nm;
a second semiconductor structure located on the first semiconductor structure; and
an active structure located between the first semiconductor structure and the second semiconductor structure.

2. The semiconductor device as claimed in claim 1, wherein the first interlayer comprises AlGaN.

3. The semiconductor device as claimed in claim 1, wherein the first semiconductor structure further comprises a first cladding layer, and the first interlayer locates between the first waveguiding layer and the first cladding layer.

4. The semiconductor device as claimed in claim 3, wherein the first semiconductor structure comprises a first intermediate layer between the first interlayer and the first cladding layer.

5. The semiconductor device as claimed in claim 1, wherein the second semiconductor structure includes a second cladding layer and a second waveguiding layer between the second cladding layer and the active structure.

6. The semiconductor device as claimed in claim 5, wherein the first waveguiding layer comprises a first refractive index, the second waveguiding layer comprises a second refractive index, and the active structure comprises a third refractive index higher than the first refractive index and the second refractive index.

7. The semiconductor device as claimed in claim 5, wherein the second semiconductor structure further comprises a carrier blocking layer between the second cladding layer and the second waveguiding layer.

8. The semiconductor device as claimed in claim 3, wherein the first cladding layer and the first interlayer comprise same element compound.

9. The semiconductor device as claimed in claim 3, wherein the first semiconductor structure further comprises a second interlayer locates between the first interlayer and the first cladding layer, and the second interlayer comprises a third band gap higher than the first band gap and lower than the second band gap.

10. The semiconductor device as claimed in claim 9, wherein the first semiconductor structure further comprises a third interlayer locates between the first interlayer and the second interlayer, and the third interlayer comprises a fourth band gap higher than the second band gap.

11. The semiconductor device as claimed in claim 9, wherein the second interlayer comprises a second thickness between 100 nm and 300 nm.

12. The semiconductor device as claimed in claim 10, wherein the third interlayer comprises a third thickness between 0.1 nm and 2 nm.

13. The semiconductor device as claimed in claim 10, wherein the second interlayer comprises GaN and the third interlayer comprises AlN.

14. The semiconductor device as claimed in claim 9, wherein the first interlayer comprises a first doping concentration and the second interlayer comprises a second doping concentration lower than the first doping concentration.

15. The semiconductor device as claimed in claim 14, wherein the second doping concentration is less than 1×10¹⁷ atoms/cm³.

16-20. (canceled)

21. The semiconductor device as claimed in claim 10, wherein the first interlayer comprises a first doping concentration and the third interlayer comprise a third doping concentration lower than the first doping concentration.

22. The semiconductor device as claimed in claim 1, wherein the second semiconductor structure comprises a mesa and a ridge protruding from the mesa.

23. The semiconductor device as claimed in claim 1, further comprising a base having a roughened structure, and the first semiconductor structure on the base.

24. The semiconductor device as claimed in claim 23, further comprising a lower electrode connecting to the roughened structure of the base.

25. The semiconductor device as claimed in claim 23, further comprising a buffer layer between the base and the first semiconductor structure.
